(19) United States
(12) Patent Application Publication
(10) Pub. No.: US 2025/0166962 A1
(43) Pub. Date: May 22, 2025

(54) METHOD FOR DISTORTION MEASUREMENT AND PARAMETER SETTING FOR CHARGED PARTICLE BEAM IMAGING DEVICES AND CORRESPONDING DEVICES

(71) Applicant: Carl Zeiss SMT GmbH, Oberkochen (DE)

(72) Inventors: Dmitry KLOCHKOV, Schwaebisch Gmuend (DE); Eugen FOCA, Ellwangen (DE)

(21) Appl. No.: 19/035,746

(22) Filed: Jan. 23, 2025

Related U.S. Application Data
(63) Continuation of application No. PCT/EP2023/070638, filed on Jul. 25, 2023.

(30) Foreign Application Priority Data
Jul. 27, 2022 (DE) 10 2022 118 875.2

(51) Int. Cl. H01J 37/26; H01J 37/28

(52) U.S. Cl. CPC H01J 37/265; H01J 37/28; H01J 2237/221

(57) ABSTRACT

A method for determining a measure of an image distortion of a charged particle beam imaging device comprises providing a plurality of images of a region of a sample using the charged ion beam device, and determining the measure of the image distortion based on displacements of corresponding objects between the plurality of images. A method of setting one or more parameters of a charged particle beam imaging device based on a measure of the image distortion as well as corresponding devices and systems is provided.

### CROSS-REFERENCE TO RELATED APPLICATION

The present application is a continuation of, and claims benefit under 35 USC 120 to, international application No. PCT/EP2023/070638, filed Jul. 25, 2023, which claims benefit under 35 USC 119 of German Application No. 10 2022 118 875.2, filed Jul. 27, 2022. The entire disclosure of each of these applications is incorporated by reference herein.

### FIELD

The present application relates to methods for measuring distortion in images captured by a charged particle beam imaging device, to methods of setting parameters of the charged particle beam imaging device based on the measure of the distortion, and to corresponding systems including charged particle beam imaging devices.

### BACKGROUND

Semiconductor structures are amongst the finest man-made structures and can suffer from different imperfections. It is known to use devices for quantitative 3D-metrology, defect-detection or defect review to look for such imperfections. Fabricated semiconductor structures are typically based on prior knowledge. The semiconductor structures are manufactured from a sequence of layers parallel to a substrate. For example, in a logic type sample, metal lines can run parallel in metal layers or HAR (high aspect ratio) structures and metal vias can run perpendicular to the metal layers. The angle between metal lines in different layers is typically either 0° or 90°. On the other hand, for VNAND type structures it is known that their cross-sections are often circular on average.

A semiconductor wafer can have a diameter of 300 mm and comprise plurality of several sites, so called dies, each comprising at least one integrated circuit pattern such as for example for a memory chip or for a processor chip. During fabrication, semiconductor wafers typically run through about 1000 process steps, and within the semiconductor wafer, about 100 and more parallel layers are often formed, comprising, for example, the transistor layers, the layers of the middle of the line, and the interconnect layers and, in memory devices, a plurality of 3D arrays of memory cells. Dimensions, shapes and placements of the semiconductor structures and patterns can be subject to several influences. In manufacturing of 3D-Memory devices, relevant processes include etching and deposition. Other involved process steps such as the lithography exposure or implantation also can have an impact on the properties of the IC-elements.

The aspect ratio and the number of layers of integrated circuits, in general, constantly increases and the structures are growing into 3rd (vertical) dimension. The current height of the memory stacks is exceeding a dozen of microns. In contrast, the features size is becoming smaller. The minimum feature size or critical dimension is below 10 nanometers (nm), for example 7 nm or 5 nm, and is approaching feature sizes below 3 nm in near future. While the complexity and dimensions of the semiconductor structures are generally growing into the third dimension, the lateral dimensions of integrated semiconductor structures are becoming smaller. Therefore, measuring the shape, dimensions and orientation of the features and patterns in 3D and their overlay with high precision can become challenging.

A common way to analyze such semiconductor devices is the use of charged particle beam imaging devices and systems like scanning electron microscopy (SEM) systems, which use one or more charged particle beams, in case of SEM systems electron beams, to scan the sample. SEM systems using more than one electron beam, also referred to as Multi-SEM, may have advantages for example with respect to throughput.

With the increasing demands on the resolution of charged particle imaging systems in three dimensions, the inspection and 3D analysis of integrated semiconductor circuits in wafers can become more and more challenging. The lateral measurement resolution of charged particle systems is typically limited by the sampling raster of individual image points or dwell times per pixel on the sample, and the charged particle beam diameter.

The sampling raster resolution can be set within the imaging system and can be adapted to the charged particle beam diameter on the sample. The typical raster resolution is 2 nm or below, but the raster resolution limit can potentially be reduced with no physical limitation. The charged particle beam diameter has a limited dimension, which generally depends on the charged particle beam operation conditions and lens. The beam resolution is generally limited by approximately half of the beam diameter. The resolution can be below 2 nm, for example even below 1 nm.

A common way to generate 3D tomographic data from semiconductor samples on the nanometer scale is the so-called slice and image approach elaborated for example by a dual beam device. A slice and image approach is described in WO 2020/244795 A1. According to the method of the WO 2020/244795 A1, a 3D volume inspection is obtained at an inspection sample extracted from a semiconductor wafer. In this method, a wafer is destroyed to obtain an inspection sample of block shape. This has been addressed by utilizing the slice and image method under a slanted angle into the surface of a semiconductor wafer, as described in WO 2021/180600 A1. According to this method, a 3D volume image of an inspection volume is obtained by slicing and imaging a plurality of cross-section surfaces of the inspection volume. In a first example for a relatively precise measurement, a large number N of cross-section surfaces of the inspection volume is generated, with the number N exceeding 100 or even more image slices. For example, in a volume with a lateral dimension of 5 micrometers (μm) and a slicing distance of 5 nm, 1000 slices are milled and imaged. This method can be very time consuming and can involve several hours for one inspection site. According to several inspection tasks, it is not required to obtain a full 3D volume image. The task of the inspection is usually to determine a set of specific parameters of semiconductor objects such as high aspect ratio (HAR)—structures inside the inspection volume. For the determination of the set of specific parameters, the number of image slices through a volume can be reduced. WO 2021/180600 A1 illustrates some methods which utilizes a reduced number of images slices. In an example, the method applies a priori information. From a single cross-section surface and a 3D volume image of a previous determination step, a property an HAR structures is derived.

For proper evaluation, in general, the images captured fulfil a desired image distortion. Image distortion may lead to artefacts in the images, which may for example be confused with defects of the device structures itself. WO2021/180600 A1 applies a model based correction to image data, for example by extracting typical model distortion polynomials from images. Typical model distortion polynomials are selected according to an imaging setup. For example, a keystone distortion may be considered under oblique imaging conditions in a slice-and-image approach with wedge-cut geometry.

This approach, however, may be inaccurate in some circumstances. For example, there is a risk of a subtraction of real defects of semiconductor features (i.e. real defects are considered as distortions and removed), or distortion may be introduced by subtraction of a too large distortion pattern from the image, corresponding to an overcorrection. The risk of inadvertently modifying the data to be measured, i.e., the images, by subtraction of model based distortions can increase with the magnitude of the distortion of the imaging process.

DE 10 2021 130 710 A1 discloses adjustment of a particle beam microscope, for example of a beam position. Images are captured with different focus settings, and if the particle beam is not adjusted correctly, an offset between images occurs.

DE 10 2021 200 799 B3 discloses a method for adjusting the focus setting of a particle beam microscope to take a tilt of the image plane into account.

### SUMMARY

To improve the distortion or at least keep the distortion of the images at an acceptable level, it is desirable to a measure for the distortion. Furthermore, based on such a measure, it is desirable improve the distortion.

According to a first aspect, the disclosure provides a method for determining a measure of an image distortion of a charged particle beam imaging device, the method comprising: providing a plurality of images of a region of a sample using the charged ion beam device; and determining the measure of the image distortion based on displacements of corresponding objects between the plurality of images.

A measure of an image distortion refers to one or more values that quantify or characterize the image distortion. With the above method, such a measure may be provided based on images captured, e.g., from a test sample. The measure may be used for monitoring purposes or for controlling the charged particle beam imaging device. The image distortion may be an image distortion based on a mechanical drift of the system.

In some embodiments, determining the measure of the image distortion based on the displacement may comprise identifying corresponding objects in the plurality of images, and measuring the coordinates of the objects in the images. Corresponding objects means the same object, e.g., the same structure, but in different images.

The plurality of images may be captured with the same focus settings, e.g., the same nominal focus setting. The nominal focus setting is the focus setting set by a controller. In such a case, changes between the images may be caused by a mechanical drift of components of the device or also vibrations.

In some embodiments, the method may comprise, prior to the identifying of corresponding objects and measuring objects coordinates, aligning the plurality of images. This may remove or average out effects affecting the complete images in the same manner.

In some embodiments, for determining the measure of the image distortion based on the displacement, the method may further include fitting a transformation to the coordinates of corresponding objects for pairs of images of the plurality of images and determining a maximum displacement value for each pair based on the fitted transformations. Through the use of the transformations, like affine transformations, errors in determining the coordinates may be at least partially eliminated.

In some embodiments, the pairs may include temporally adjacent pairs, i.e., pairs of images captured by the charged particle beam imaging device immediately one after the other in time. In other embodiments, other pairs, for example all possible pairs of images, may be used.

In some embodiments, the method may further comprise determining the measure of the image distortion as a function of the maximum displacement values for the different pairs. In other words, the measure is determined based on a plurality of the maximum displacement values mentioned above.

In some embodiments, the function may be selected from the group consisting of a maximum determining function (yielding the maximum of all maximum displacement values), in minimum determining function (yielding the minimum of all maximum displacement values), an averaging function (yielding the average of all maximum displacement values), and a median function (yielding the median of all maximum displacement values).

In some embodiments, the method may further comprise normalizing the measure of the image distortion to a size of the portion of the sample captured by the images, also referred to as real dimension of the images, i.e., the dimensions the portion of the sample captured in the image has in reality. In this way, measures of the image distortion for different sizes of the portion become comparable.

In some embodiments, the charged particle beam imaging device may be a multi-beam scanning electron microscope, which may enable a high throughput by the use of multiple beams.

According to a second aspect, the disclosure provides a method of controlling a charged particle beam imaging device, the method comprising: providing a measure of an image distortion of the charged particle beam imaging device; and setting at least one parameter of the charged particle beam imaging device based on the measure of the image distortion.

In this way, in some embodiments one or more parameters of the charged particle beam device may be optimized. The setting of the at least one parameter may be performed automatically or may be performed at least partially based on user input, where the method automatically provides assistance to the user, for example by displaying the measure of the distortion depending on the parameter to be set.

In some embodiments, in the method of the second aspect the measure of the image distortion may be provided with any of the methods of the first aspect.

In some embodiments, the providing of the measure of the image distortion may performed for a plurality of values of the at least one parameter, and wherein the at least one parameter is set based on a threshold distortion. In this way, in some embodiments an image distortion smaller than indicated by the threshold distortion may be obtained.

In some embodiments, the at least one parameter may comprise at least one of a frame rate, a dwell time, an image resolution, a beam current, a sample mounting parameter, a milling parameter, and imaging angle of the charged particle beam imaging device and a scanning parameter of the charged particle beam imaging device. Therefore, various parameters may be optimized. Some of these parameters may be used to balance a higher mechanical drift, e.g. a higher frame rate (less time for a single image) makes the images less prone to effects from mechanical drift.

In some embodiments, setting the at least one parameter may further be based on a predefined signal to noise ratio threshold. In this way, signal to noise ratio of the images may additionally be taken into account.

In some embodiments, the parameter may comprise an image resolution, wherein the image resolution is selected to satisfy both a threshold for the distortion and the predefined signal to noise ratio threshold. By setting the image resolution, a dwell time for individual pixels may be selected to achieve a desired signal to noise ratio, and a frame time for acquiring an image may be selected to achieve a desired distortion. Therefore, a balance may be found between different desired properties, for example signal-to-noise ratio, where a higher dwell time is desirable, and distortion, where a shorter time for capturing an image (i.e. higher frame rate) may be helpful.

According to a third aspect, the disclosure provides a device, comprising a controller configured to: receive a plurality of images of a region of a sample using a charged ion beam device; and determine a measure of an image distortion based on displacements of corresponding objects between the plurality of images.

According to a fourth aspect, the disclosure provides a device is provided, comprising a controller configured to: provide a measure of an image distortion of a charged particle beam imaging device; and set at least one parameter of the charged particle beam imaging device based on the measure of the image distortion.

In some embodiments, the devices of the third and fourth aspects may be configured to perform any of the methods of the first and second aspect. The explanations given above for the methods also apply to the devices.

Furthermore, according to an aspect, the disclosure provides a system, comprising: any device of the third and/or fourth aspect; and a charged particle beam imaging device.

### BRIEF DESCRIPTION OF THE DRAWINGS

FIG. 1 is a block diagram of a device according to an embodiment.

FIG. 2 is a flowchart of a method according to an embodiment.

FIG. 3 is a diagram of an example charged particle beam imaging device.

FIG. 4 is a perspective view for explaining operation of the charged particle beam imaging device of FIG. 3.

FIG. 5 illustrates example images of semiconductor structures.

FIG. 6 illustrates an example image of a semiconductor structure.

FIG. 7 is a flowchart illustrating a method according to an embodiment.

FIG. 8 is a diagram illustrating a relationship between frame time and distortion.

FIG. 9 is a diagram illustrating a relationship between measurement accuracy and frame time.

FIG. 10 is a diagram illustrating optimization of the dwell time.

FIG. 11 is a diagram illustrating optimization of the frame time.

### DETAILED DESCRIPTION

In the following, various embodiments will be described referring to the attached drawings. These embodiments are given by way of example only and are not to be construed as limiting in any way.

Features from different embodiments may be combined to form further embodiments. Variations, modifications and details described with respect to the one of the embodiments are also applicable to other embodiments and will therefore not be described repeatedly.

In the drawings, corresponding elements are denoted with the same reference numerals.

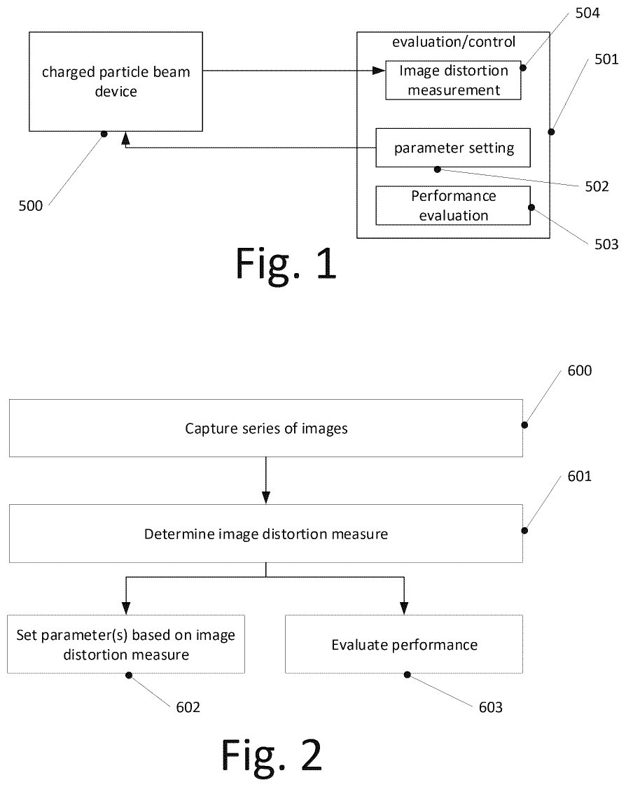

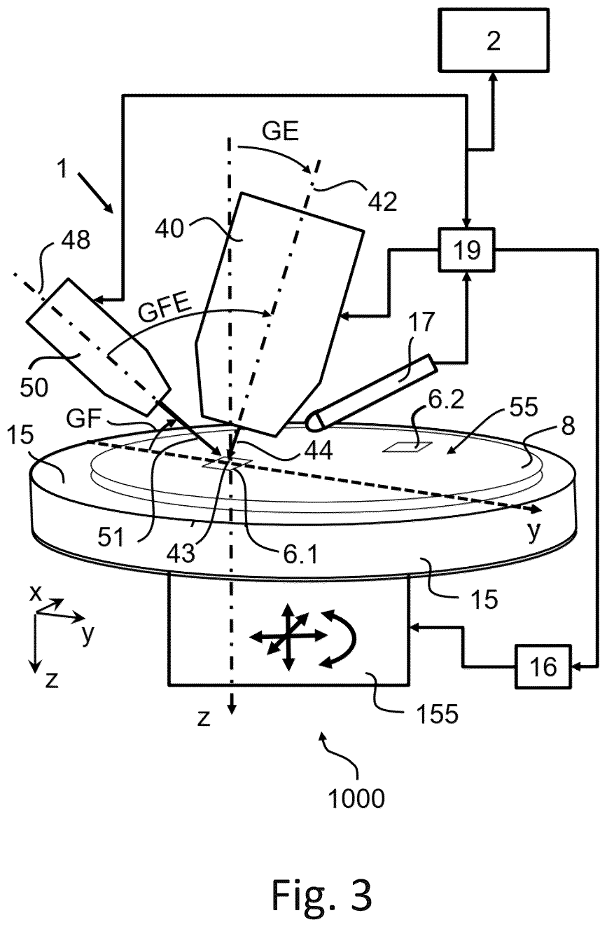

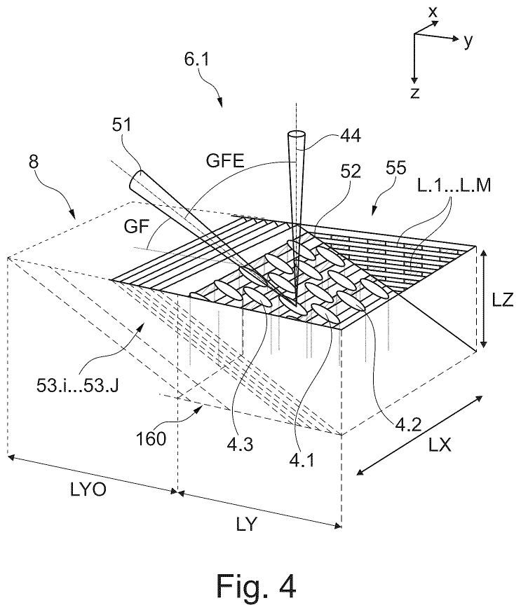

FIG. 1 illustrates an inspection system, e.g. wafer inspection system, according to an embodiment. The system of FIG. 1 includes a charged particle beam imaging device 500 configured to provide images of semiconductor structures formed on a wafer, for example HAR-structures mentioned above. In other embodiments, instead of semiconductor structures formed on a wafer or a chip die, masks used for manufacturing semiconductor devices may be inspected. However, in the following semiconductor structures will be used as non-limiting examples. Charged particle beam imaging device 500 in various embodiments may be a scanning electron microscopy (SEM) device, as described and mentioned in the introductory portion or as described further below referring to FIGS. 3 and 4. Other charged particle beam imaging devices known to the skilled person may also be used, for example devices using ion beams instead of electron beams.

Charged particle beam imaging device 500 provides images of the semiconductor structures. In some embodiments, this may include a milling process, to provide a 3-dimensional tomography of the semiconductor devices.

Images captured by charged particle beam imaging device 500 may include image distortions. Image distortions in charged particle beam imaging devices are mainly caused by three factors:
(i) Distortions caused by the configuration of the charged particle beam imaging device itself, for example the part responsible for the imaging, for example the so-called imaging column. Such distortions may be similar to or correspond to optical aberrations. They may for example be caused by the scanning process (scanning distortion), or a distortion from a specific geometry of the imaging process.
(ii) Charging of the sample to be examined, for example of semiconductor structures thereon. This distortion source depends on pre-charging conditions and from an actual accumulated charge during a measurement process. Local sample charges typically disappear due to diffusion processes after a short time. As the imaging of a charged particle beam imaging device relies, as the name says, on charged particles, charge on the sample can influence the image, i.e. cause distortions.

Pre-charging can be minimized by a slice-and-image process and charge accumulation can be mitigated by adapted scanning strategies, for example by an interlaced scanning of separated lines, such that neighboring scanning lines are only scanned after a decay time of locally accumulated charges. In other words, such a strategy tries to avoid that a current measurement at a current scanning position is overly influenced by previous measurements at previous scanning positions, which cause a charging.
(iii) Mechanical drift of the sample during the image acquisition. This means that during image acquisition, the sample may move, for example due to acoustic noise and the like. For example, vibrations may cause a movement of a stage on which the wafer is mounted, of the imaging system (scanner, scanning optics etc.) or both.

While the cause (i) above is comparatively constant based on the geometry and implementation of the charged particle beam imaging device 500 and therefore comparatively easily compensated mathematically, and the charging of the sample/wafer under (ii) can be mitigated by some strategies, dealing with mechanical drift may be more difficult, as for example vibrations causing mechanical drift may also depend on the environment.

Charged particle beam imaging device 500 is coupled to an evaluation/control device 501, for example a computer or other processing system. Evaluation/control device 501 may control charged particle beam imaging device 500 to capture a series of images of the same objects (for example semiconductor structures), possibly with milling steps beforehand or in between. Based on the series of images, indicated by block 504 evaluation/control device 501 performs an image distortion measurement, i.e. provides one or more measurement values characterizing the distortion. Such one or more measurement values characterizing the distortion will be referred to as “measure of the image distortion” or short “measure of the distortion” herein.

In some embodiments, the measure of the distortion may be used to monitor the wafer inspection process, and in case the measure of the distortion for example becomes too high indicating a high distortion, measurements may be classified as not reliable. In other words as indicated by a block 503, evaluation/control device 501 evaluates the performance of charged particle beam imaging device 500 based on the measure of the distortion. Additionally or alternatively, in other embodiments, as indicated by a block 502, evaluation/control device 501 may set parameters of charged particle beam imaging device 500 based on the measure of the distortion, for example in order to reduce the distortion. Such parameters to be set may include for example a beam current of the charged particle beam, an acceleration voltage, a dwell time, i.e. how long the beam remains at one place for measurement, a frame time (i.e. how long it takes to capture a frame), an image resolution, also referred to as frame resolution, scanning parameters etc. By providing the measure of the distortion, optimization of these parameters to find a “sweet spot” in the parameter space may be facilitated.

Detailed implementation possibilities of the image distortion measurement and the setting of parameters as well as an example implementation of charged particle beam imaging device 500 will be explained further below.

FIG. 2 is a flow chart illustrating a method according to an embodiment, corresponding to the operation of the inspection system of FIG. 1. The method of FIG. 2 therefore may be implemented in the system of FIG. 1 or in the systems and devices discussed below. At a step 600, the method comprises capturing a series of images using a charged particle beam imaging device, for example using charged particle beam imaging device 500 of FIG. 1, of a sample. The images include the same or corresponding structures. In some embodiments, the sample may be a test wafer or test sample specifically used for determining the distortion.

At a step 601, a measure of the image distortion is determined as explained above. For determining the measure of the image distortion, for example displacements of corresponding objects between images in the series of images may be used.

At a step 602, the method comprises setting parameters of the charged particle beam imaging device, for example charged particle beam imaging device 500, based on the measure of the distortion.

At a step 603, the method comprises evaluating the performance based on the measure of the distortion, for example to detect when the distortion is at an acceptable value.

Step 602 and 603 may both be performed, or only one of them may be performed. In some embodiments, the method is performed repetitively, for example for evaluating the performance in step 603 in regular or irregular intervals. In some embodiments, during a first run step 602 may be performed to set parameters, and then in subsequent runs step 603 may be performed. In case in step 603 the measure then indicates an unacceptable distortion, the method may be repeated with step 602, to readjust the parameters.

Next, example implementations of the system of FIG. 1 and the method of FIG. 2 will be described. Other implementations may also be used.

First, referring to FIGS. 3 and 4, an example implementation of charged particle beam imaging device 500 will be described. Other implementations, for example other charged particle beam imaging devices, may also be used.

An example charged particle beam imaging device 1000 for 3D volume inspection is illustrated in FIG. 3, which is an example for charged particle beam imaging device 500 of FIG. 1. The charged particle beam imaging device 1000 is configured for a slice and imaging method under wedge cut geometry with a dual beam device 1. For a wafer 8, several measurement sites, comprising measurement sites 6.1 and 6.2, are defined in a location map or inspection list generated from an inspection tool or from design information. The wafer 8 is placed on a wafer support table 15. The wafer support table 15 is mounted on a stage 155 with actuators and position control. Movement of stage 155, for example due to vibrations, is an example cause for image distortions. Actuators and mechanisms for precision control for a wafer stage such as laser interferometers are known in the art. A control unit 16 configured to control the wafer stage 155 and to adjust a measurement site 6.1 of the wafer 8 at the intersection point 43 of the dual-beam device 1. Control unit 16 may be implemented together with evaluation/control device 501 of FIG. 1, or may be a separate control unit. The dual beam device 1 comprises a FIB column 50 with a FIB optical axis 48 and a charged particle beam (CPB) imaging system 40 with optical axis 42. Vibration or other displacement of FIB column 50 and/or CPB imaging system 40 may also cause image distortions.

At the intersection point 43 of both optical axes of FIB and CPB imaging system, the wafer surface is arranged at a slant angle GF to the FIB axis 48. FIB axis 48 and CPB imaging system axis 42 include an angle GFE and the CPB imaging system axis forms an angle GE with normal to the wafer surface 55. In the coordinate system of FIG. 3, the normal to the wafer surface 55 is given by the z-axis.

The focused ion beam (FIB) 51 is generated by the FIB-column 50 and is impinging under angle GF on the surface 55 of the wafer 8. Slanted cross-section surfaces are milled into the wafer by ion beam milling at the inspection site 6.1 under approximately the slant angle GF. In the example of FIG. 3, the slant angle GF is approximately 30°. The actual slant angle of the slanted cross-section surface can deviate from the slant angle GF by up to 1° to 4° due to the beam divergence of the focused ion beam, for example a Gallium-Ion beam. With the charged particle beam imaging system 40, inclined under angle GE to the wafer normal, images of the milled surfaces are acquired. In the example of FIG. 3, the angle GE is about 15°. However, other arrangements are possible as well, for example with GE=GF, such that the CPB imaging system axis 42 is perpendicular to the FIB axis 48, or G=0°, such that the CPB imaging system axis 42 is perpendicular to the wafer surface 55.

During imaging, a beam of charged particles 44 is scanned by a scanning unit of the charged particle beam imaging system 40 along a scan path over a cross-section surface of the wafer at measurement site 6.1, and secondary particles as well as scattered particles are generated. Particle detector 17 collects at least some of the secondary particles and scattered particles and communicates the particle count with a control unit 19. Other detectors for other kinds of interaction products may be present as well. Control unit 19 is in control of the charged particle beam imaging column 40, of FIB column 50 and connected to a control unit 16 to control the position of the wafer mounted on the wafer support table via the wafer stage 155. Control unit 19 communicates with operation control unit 2, which triggers placement and alignment for example of measurement site 6.1 of the wafer 8 at the intersection point 43 via wafer stage movement and triggers repeatedly operations of FIB milling, image acquisition and stage movements. Control units 19, 16, 2 may be implemented as separate entities, or may be integrated in a single control device, and/or may be integrated with or separate from device 501 of FIG. 3.

Each new intersection surface is milled by the FIB beam 51, and imaged by the charged particle imaging beam 44, which is for example scanning electron beam or a Helium-Ionbeam of a Helium ion microscope (HIM).

In an example, the dual beam system comprises a first focused ion beam system 50 arranged at a first angle GF1 and a second focused ion column arranged at the second angle GF2, and the wafer is rotated between milling at the first angle GF1 and the second angle GF2, while imaging is performed by the imaging charged particle beam column 40, which is for example arranged perpendicular to the wafer surface.

FIG. 4 illustrate further details of the slice and imaging method in the wedge cut geometry. By repetition of the slicing and imaging method in wedge-cut geometry, a plurality of J cross-section image slices comprising image slices of cross-section surfaces 52, 53.i . . . 53.J is generated and a 3D volume image of an inspection volume 160 at an inspection site 6.1 of the wafer 8 at measurement site 6.1 is generated. FIG. 4 illustrates the wedge cut geometry at the example of a 3D-memory stack. The cross-section surfaces 53.1 . . . 53.N are milled with a FIB beam 51 at an angle GF of approximately 30° to the wafer surface 9, but other angles GF, for example between GF=20° and GF=60° are possible as well. FIG. 4 illustrates the situation, when the surface 52 is the new cross-section surface which was milled last by FIB 51. The cross-section surface 52 is scanned for example by SEM beam 44, which is in the example of FIG. 4 arranged at normal incidence to the wafer surface 55, and a high-resolution cross-section image slice is generated. The cross-section image slice comprises first cross-section image features, formed by intersections with high aspect ratio (HAR) structures or vias (for example first cross-section image features of HAR-structures 4.1, 4.2, and 4.3) and second cross-section image features formed by intersections with layers L.1 . . . . L.M, which comprise for example SiO2, SiN- or Tungsten lines. Some of the lines are also called “word-lines”. The maximum number M of layers is typically more than 50, for example more than 100 or even more than 200. The HAR-structures and layers extend throughout most of the volume in the wafer but may comprise gaps. The HAR structures typically have diameters below 100 nm, for example about 80 nm, or for example 40 nm. The cross-section image slices contain therefore first cross-section image features as intersections or cross-sections of the HAR structure footprints at different depth (Z) at the respective XY-location.

In case of vertical memory HAR structures of a cylindrical shape, the obtained first cross-sections image features are circular or elliptical structures at various depths determined by the locations of the structures on the sloped cross-section surface 52. The memory stack extends in the Z-direction perpendicular to the wafer surface 55. The thickness d or minimum distances d between two adjacent cross-section image slices is adjusted to values typically in the order of few nm, for example 30 nm, 20 nm, 10 nm, 5 nm, 4 nm or even less. Once a layer of material of predetermined thickness d is removed with FIB, a next cross-section surface 53.i . . . 53.J is exposed and accessible for imaging with the charged particle imaging beam 44.

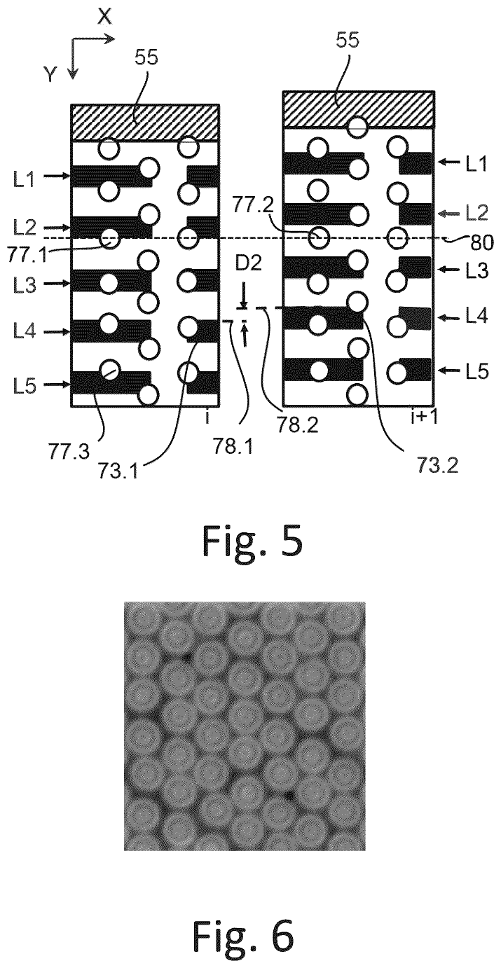

FIG. 5 illustrates an ith and (i+1)-th cross-section image slice at an example. The vertical HAR structures appear in the cross-section image slices as first cross-section image features, for example first cross-section image features 77.1, 77.2 and 77.3. Since the imaging charged particle beam 44 is oriented parallel to the HAR structures, the first cross-section image features representing for example an ideal HAR structures would appear at same y-coordinates. For example, first cross-section image features of ideal HAR structures 77.1 and 77.2 are centered at line 80 with identical Y coordinate of the ith and (i+1)-th image slice. The cross-section image slices further comprise a plurality of second cross-section image features of a plurality of layers comprising for example layers L1 to L5, for example second cross-section image features 73.1 and 73.2 of layer L4. The layer structure appears as segments of stripes along X-direction in the cross-section image slices. The position of these second cross-section image features representing the plurality of layers, here shown layers L1 to L5, however, changes with each cross-section image slice with respect to the first cross-section image features. As the layers intersect the image planes at increasing depth, the position of the second cross-section image features changes from image slice i to image slice i+1 in a predefined manner. The upper surface of layer L4, indicated by reference numbers 78.1, 78.2, are displaced by distance D2 in y direction. From determining the positions of the second cross-section image features, for example 78.1 and 78.2, the depth map Z(x,y) of a cross-section image can be determined. By feature extraction of the second cross-section image features, such as edge detection or centroid computation and image analysis, and according the assumption of the same or similar depth of the second cross-section image features, the determination of the lateral position as well as the relative depth of the first cross-section image features in cross-section image slices is therefore possible with high precision. Due to the planar fabrication techniques involved in the fabrication of a wafer, layers LI1 to L5 are at constant depth over a larger area of a wafer. The depth maps of first cross-section image slices can at least be determined relative the depth of second cross-section images features in the M layers. Further details for the generation of the depth maps ZJ(x,y) for the cross-section image slices are described in WO 2021/180600 A1.

A plurality of J cross-section image slices acquired in this manner covers an inspection volume of the wafer 8 at measurement site 6.1 and is used for forming of a 3D volume image of high 3D resolution below for example 10 nm, such as below 5 nm. The inspection volume 160 (see FIG. 4) typically has a lateral extension of LX=LY=5 μm to 15 μm in x-y plane, and a depth LZ of 2 μm to 15 μm below the wafer surface 55. The full 3D volume image generation according WO 2021/180600 A1 typically involves milling cross-section surfaces into the surface 55 of the wafer 8 with a larger extension in y-direction as the extension LY. In this example, the additional area with extension LYO is destroyed by the milling of the cross-section surfaces 53.1 to 53.N. In a typical example, the extension LYO exceeds 20 μm. The operation control unit 2 is configured to perform a 3D inspection inside an inspection volume 160 in a wafer 8. The operation control unit 2 is further configured to reconstruct the properties of semiconductor structures of interest from the 3D volume image. In an example, features and 3D positions of the semiconductor structures of interest, for example the positions of the HAR structures, are detected by the image processing methods, for example from HAR centroids. A 3D volume image generation including image processing methods and feature based alignment is further described in WO 2020/244795 A1.

FIG. 6 shows another example image of HAR structures, in this case a DRAM sample, captured with an angle perpendicular to the wafer surface. These structures include a plurality of columns, each column including a plurality of rings, as can be seen in FIG. 6.

For determining the measure of the distortion, as mentioned above (for example step 600 of FIG. 2) a series of images containing the same portion of a semiconductor device and including a plurality of objects may be taken. The images of FIGS. 5 and 6 are corresponding examples. In some embodiments, no milling is performed, such that the same image plane is captured repetitively. In other embodiments, milling may be performed before image capture and/or between capturing different images of the series, as long as the same objects (for example same columns) are included in the image. In some embodiments, the milling may remove surface charging from the sample, contamination from the sample or both.

As mentioned above, the sample, for example test wafer, may be a wafer dedicated for testing and determining the distortion, and may also be used for other purposes like defect analysis like defect analysis in some embodiments. Such other purposes will not be dealt with within the present application in detail. In some embodiments, the sample may only include part of a wafer, for example a diced wafer with semiconductor structures thereon, or may be a mask used for manufacturing semiconductor devices or part thereof.

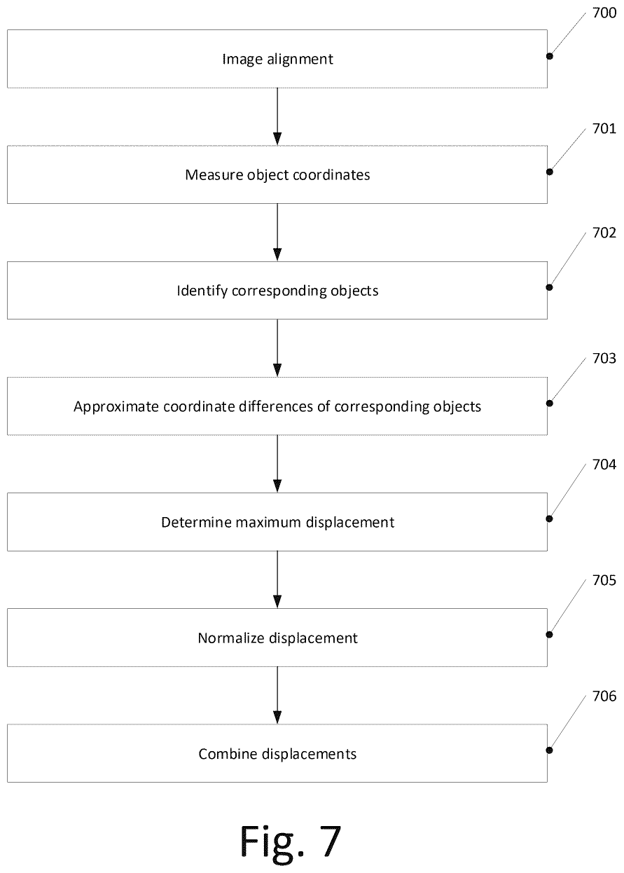

Based on the series of images, then a measure of the distortion is obtained, basically based on changes of the positions, referred to as displacements, of objects between the images of the series of images. A series of images means at least two images, for example three images or more, four images or more, five images or more etc. FIG. 7 is a flowchart illustrating determination of a measure of the distortion according to an embodiment. In other embodiments, some of the steps shown may be omitted, or may be replaced by alternative steps.

For the purpose of the description of FIG. 7, the plane of the images will be referred to as the x-y plane, and the z direction is perpendicular thereto.

In step 700, the images are aligned with each other, meaning that a translation is performed on the images such that, if it were a distortion free image capturing and the structures would be free of errors, corresponding objects would be at the same positions. In some embodiments, alignment markers as discussed above with respect to FIG. 5 may be used for alignment. In other embodiments, for example in case of a structure as in FIG. 6, the general structure of the image is known by design of the semiconductor devices, and the alignment may be based on this general structure. For example, in FIG. 6 the columns are arranged in a hexagonal manner, and the distances between the columns may be known by design. Also, WO 2021/180600 A1 mentioned above discusses approaches for image alignment. Generally, any method for image alignment known to the skilled person may be used.

At step 701, the coordinates of the objects are measured. For this, the objects are detected in the image. For object detection, any conventional method may be used. One approach known to the skilled person is the use of machine learning techniques, where for example in a plurality of images of corresponding semiconductor structures the objects are annotated and then provided to a machine learning logic like a neural network. For example, for identifying the columns in FIG. 6, images including such columns may be annotated, i.e. the columns may be marked. In other embodiments, the individual rings of the columns may be annotated, such that the individual rings are used as objects.

The object coordinates may be measured at any point of the object, as long as the point is the same for all images. For example, for the columns or rings of FIG. 6, the center of the columns or rings may be used as coordinates of the objects. In other embodiments, for other objects coordinates like the coordinates of a lower left corner, upper left corner etc. may be used. In another embodiment, in step 701 a cross-correlation based detection of the object and subsequent measuring of the coordinates can be obtained.

It should be noted that coordinates may be measured in pixels (picture elements) in the images, as long as all images have the same scale, or in “real life” units like nanometres. As the general size of the structures is known by the design from the structures, it is straightforward to convert one kind of measure (pixels) to the other (i.e. for example nanometre) for example, this means, refer to FIG. 6, that for each of the columns shown the coordinate is determined in all images. In other embodiments, only some of the objects may be used, for example only some of the columns in FIG. 6 or some of the structures of FIG. 5, instead of using all objects.

In step 702, corresponding objects are identified in the images, i.e. the objects are “traced” to the stack of images. As a result of the identifying in step 702, a list of coordinates of each object in each image is obtained. Possible differences between the coordinates of the respective objects in different images are assumed to be caused by either a variable distortion of the images, i.e. a distortion which is not a translation affecting the image as a whole, or inaccuracies in the determined object coordinates (like all measurements, the measuring of the object coordinates at 701 may have a certain measurement error). Due to the image alignment in step 700, any translation between the images as a whole or average translations of the images as a whole were eliminated and do not contribute to the differences.

In step 703, the differences between the coordinates of corresponding objects in image pairs is approximated by fitting a predefined transformation to the pairs of objects coordinates, for example an affine transformation or higher-order non-linear transformation. The fitting may be performed between any pairs of the images, e.g. for all available pairs, between temporally adjacent images only (i.e. images taken immediately one after the other), or between any other selection of pairs of images. An affine translation, in this respect, is essentially a linear translation including offset, rotation, scaling, and shearing. In a fitting procedure, the transformation is applied to the objects coordinates in the first image to obtain the transformed object coordinates. The parameters of the transformation (for example the elements of the affine transformation matrix) are varied to minimize the summed deviations of the transformed object coordinates from the respective object coordinates in the second image, to thus obtain a best-fit transformation.

In step 704, then a maximum displacement, for example in physical units like nanometres, caused by the best-fit transformations is calculated. For example, one applies the best-fit transformation found in the previous step to the coordinates of all pixels in the first image and computes the maximum displacement of the transformed pixel coordinates with respect to their original coordinates. This maximum displacement may then be used as a measure for the distortion.

In other embodiments, in step 705 the maximum displacement may be normalized to the physical size of the image. Physical size of the image refers to the actual size of the semiconductor structure captured by the image, for example in micrometers.

Furthermore, also optionally, instead of taking the maximum displacements computed for all transformations between pairs of images as measure, i.e. a plurality of value, in step 706 the maximum displacements calculated for the different pairs may be combined to give a single value as the measure of the distortion. For example, an average, median, maximum, minimum or a certain quantile of the computed maximum displacement over all considered pairs of images may be used to characterize the distortion in the considered series of images.

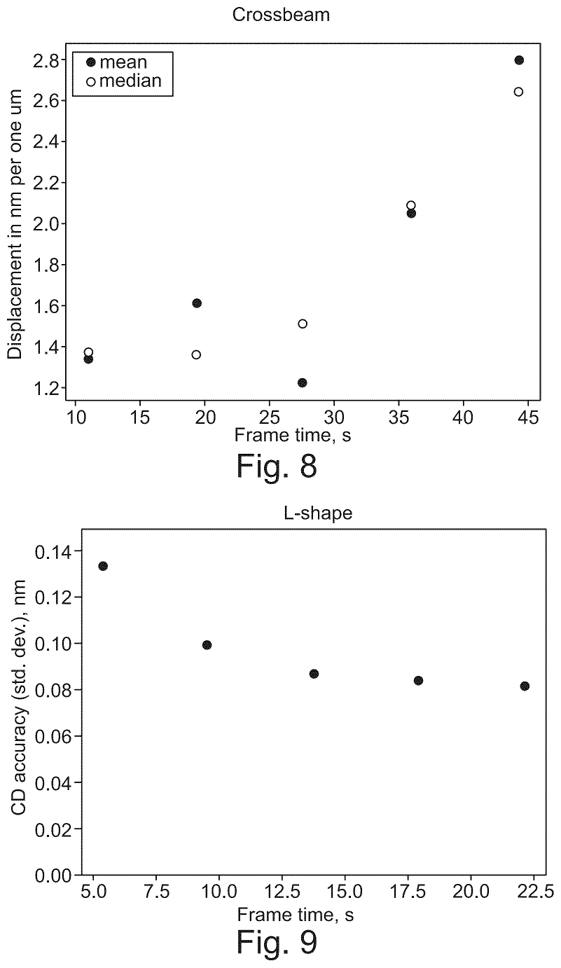

This figure of merit may then be used for performance evaluation by block 503 of FIG. 3 or in step 603 of FIG. 2. In other embodiments, parameters of the charged particle beam imaging device, for example device 500 of FIG. 1 or device 1000 of FIG. 3, as explained above with respect to block 502 of FIG. 1 or step 602 of FIG. 2. Examples for parameter setting will be described next referring to FIGS. 8 to 11.

One example for parameter optimization is the optimization of the frame time of the images, i.e. the time used to acquire the image, the dwell time, i.e., the time used to measure a single spot of the sample corresponding to one pixel of the image, and/or a frame resolution. The frame time corresponds to the dwell time times the number of pixels in the image plus an offset, such that these parameters are linked.

FIG. 8 is a diagram illustrating the displacement in nm/um determined by the embodiment of FIG. 7, including step 705 and 706 (i.e. displacement in nm normalized to 1 μm image size) as an average (mean) value of the maximum displacements calculated for the image pairs and as a median value. As can be seen, when the frame time exceeds about 30 seconds, a sharp increase of the displacement can be observed. This indicates that an image drift is a main cause for the distortion.

FIG. 9 is a graph showing a measured error (standard deviation of critical dimension (CD) measurements of memory channels like the column structures in FIG. 6). With such memory structures, the critical dimension is specifically used for the diameters of the memory channels/columns. As can be seen here, and as expected, the error of the measurement decreases with increased frame time because a larger frame time yields a higher signal to noise ratio in the image, which is a common effect for longer measurement times. Therefore, in this example the parameter setting at block 502 or FIG. 1 or step 602 of FIG. 2 may strive to find a balance between an acceptable distortion and a measurement accuracy. For example, thresholds may be given for distortion and desired accuracy, and based on these thresholds a frame time may be selected.

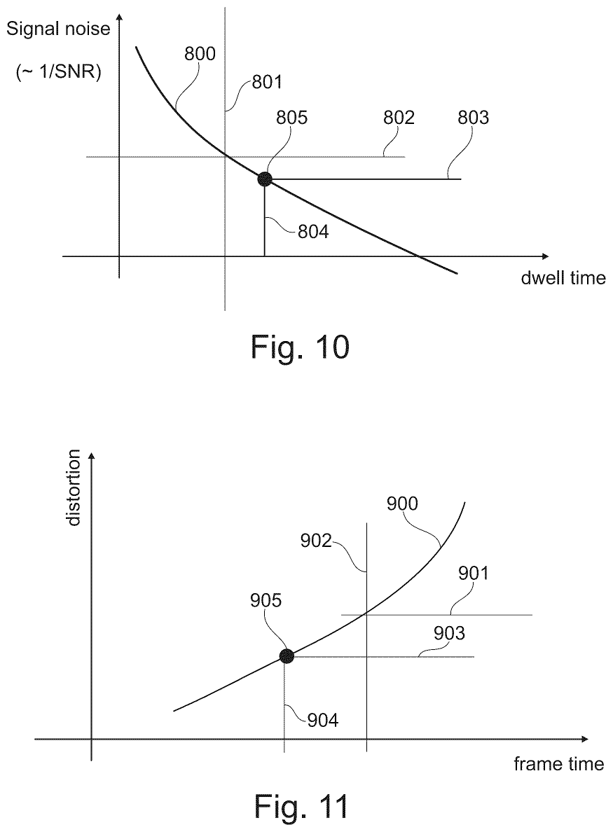

The tradeoff between measurement accuracy as shown in FIG. 9 and distortion as shown in FIG. 8 will be further illustrating referring to FIGS. 10 and 11. In FIG. 10, a curve 100 shows the signal noise, which as approximately inverse proportional to the signal to noise ratio over the dwell time for a single measurement spot, i.e. a single pixel. In order to reduce the signal noise, for example due to shot noise, the dwell time has to be above a certain threshold. For example, a line 801 shows a typical minimum dwell time for typical electron current levels in SEMs, which may be about 100 ns, which yields a typical level for CD noise, dCD, >0.1 nm. If a certain threshold noise level as for example indicated by a line 803 is desired, for example dCD>0.07 nm, a corresponding higher minimum dwell time as indicated by line 804, for example >250 ns, is involved. The threshold selected depends on the electron current and the secondary electrons/back-scattered electrons (SE/BSE) yield and therefore depends on material contrast and collection efficiency of SE/BSE. The former is given by the object, for example wafer or mask, the latter is limited by geometry, for example the working distance. Typical electron current levels in SEM devices are about 200 to 300 nA. Typical range for dwell times are 100 ns to 500 ns.

A higher dwell time in particular means a higher dose of charged particle, which increases the signal to noise ratio and correspondingly decreases the signal noise. For example, the dose corresponds to the dwell time multiplied with the charged particle current.

Furthermore, FIG. 11 shows, in a curve 900, the distortion over frame time. As explained above, in order to reduce the distortion, i.e. the impact of vibrations on pattern distortion, the frame time has to be below a certain threshold. A line 901 shows a typical level for distortion caused by vibration, for example DX<2 nm. In the example shown according to line 902 to a certain frame time. For a desired distortion level as indicated by a line 903, as indicated by line 904 the frame time has to be lower. For example, for a distortion smaller than 1.5 nm a frame time<15 seconds may be involved, corresponding to operating point 905. This corresponds to operating point 805.

The threshold for the frame time may be tool-specific and environment-specific. For example, tools, i.e. charged particle beam imaging devices used for wafer or mask inspection) with a high precision control and/or having damping components to reduce vibrations may allow longer dwell times than tools in a noisy environment without such counter measures.

As already mentioned above, the frame time used for the x-axis in FIG. 11 and the dwell time of FIG. 10 are related via the number of pixels in the image. The frame time is the number of pixels x the dwell time+an offset for example from scanning flyback (e.g. jumping to the start of the line from the beginning of the last line in case of a linewise scanning) and other influences.

Thus, in some embodiments, based on a desired maximum dwell time to achieve a low signal noise as shown in FIG. 10 and the desire to have a low frame time below a threshold as explained with respect to FIG. 11, a maximum number of pixels per image and therefore a maximum image size, also referred to as frame size, may be determined. For example, from a desire for a dCD accuracy below 0.07 nm as explained above with respect to FIG. 10, a dwell time of 350 ns minimum is derived. From a desire for a distortion dx<1.5 nm, a frame time below 15 seconds is determined. Assuming for example 10% offset time, a frame of approximately 38.5 MPixel can be acquired, for example a frame of about 6200×6200 Pixels. This pixel number may be calculated by dividing the desired frame time by the dwell time+the offset, according to the formula given above.

Therefore, in embodiments, as a parameter based on the measure of the distortion, an image size in pixels may be determined.

As mentioned above, for example also the electron current level plays a role in determining the noise. If the electron current level is adjustable (or current level of ions in case of an ion beam device), this parameter may additionally be taken into account. Other parameters include the scanning path, sample mounting conditions, milling, imaging angle, number of cross-section images, predetermined image quality comprising distortion, noise level etc.

The parameters may also depend on the samples. Parameters determined as above may be stored for various samples and then used later when characterizing the samples depending on the type of sample.

Although specific embodiments have been illustrated and described herein, it will be appreciated by those of ordinary skill in the art that a variety of alternate and/or equivalent implementations may be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof.

What is claimed is:

1. A method, comprising:
obtaining a plurality of images of a region of a sample using a charged ion beam device; and
determining a measure of the image distortion based on displacements of corresponding objects between the plurality of images.

2. The method of claim 1, wherein determining the measure of the image distortion based on the displacement comprises:
identifying corresponding objects in the plurality of images; and
measuring the coordinates of the objects in the images.

3. The method of claim 2, further comprising, prior to identifying the corresponding objects and measuring the coordinates of the objects, aligning the plurality of images.

4. The method of claim 2, wherein determining the measure of the image distortion based on the displacement further comprises:
fitting a transformation to the coordinates of the corresponding objects for pairs of images of the plurality of images; and
determining a maximum displacement value for each pair of images based on the fitted functions.

5. The method of claim 4, wherein the pairs of images comprise temporally adjacent pairs.

6. The method of claim 5, comprising determining the measure of the image distortion as a function of the maximum displacement values for the different pairs.

7. The method of claim 6, wherein the function comprises a member selected from the group consisting of a maximum determining function, in minimum determining function, an averaging function, and a median function.

8. The method of claim 1, further comprising normalizing the measure of the image distortion to a size of the region of the sample captured by the images.

9. The method of claim 1, wherein the charged particle beam imaging device comprises a multi-beam scanning electron microscope.

10. The method of claim 1, wherein the plurality of images is obtained use a same focus setting of the charged ion beam device.

11. A device comprising:
a controller configured to:
provide a measure of an image distortion of a charged particle beam imaging device; and
set a parameter of the charged particle beam imaging device based on the measure of the image distortion.

12. A system, comprising:
the device of according to claim 11; and
a charged particle beam imaging device.

13. A method, comprising:
providing a measure of an image distortion of a charged particle beam imaging device; and
setting a parameter of the charged particle beam imaging device based on the measure of the image distortion, thereby controlling the charged particle beam imaging device.

14. The method of claim 13, providing the measure of the image distortion of the charged particle beam comprises:
obtaining a plurality of images of a region of a sample using the charged ion beam device; and
determining the measure of the image distortion based on displacements of corresponding objects between the plurality of images.

15. The method of claim 14, wherein the plurality of images is obtained use a same focus setting of the charged ion beam device.

16. The method of claim 13, wherein providing the measure of the image distortion is performed for a plurality of values of the parameter, and wherein the parameter is set based on a threshold distortion.

17. The method of claim 13, wherein the parameter comprises at least one member selected from the group consisting of a frame rate of the charged particle beam imaging device, a dwell time of the charged particle beam imaging device, an image resolution of the charged particle beam imaging device, a beam current of the charged particle beam imaging device, a sample mounting parameter of the charged particle beam imaging device, a milling parameter of the charged particle beam imaging device, and imaging angle of the charged particle beam imaging device and a scanning parameter of the charged particle beam imaging device.

18. The method of claim 13, wherein setting the parameter is further based on a predefined signal to noise ratio threshold.

19. The method of claim 18, wherein the parameter comprises an image resolution selected to satisfy both a threshold for the distortion and the predefined signal to noise ratio threshold.

20. A device, comprising:
a controller configured to:
obtain a plurality of images of a region of a sample using a charged ion beam device; and
determine a measure of an image distortion based on displacements of corresponding objects between the plurality of images.

21. A system, comprising:
the device of according to claim 20; and
a charged particle beam imaging device.
